(19) United States
(12) Patent Application Publication
(10) Pub. No.: US 2026/0052961 A1
(43) Pub. Date: Feb. 19, 2026

(54) METHOD OF FABRICATING PACKAGE STRUCTURE

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW)

(73) Assignee: Taiwan Semiconductor Manufacturing Company, Ltd., Hsinchu (TW)

(21) Appl. No.: 18/808,052

(22) Filed: Aug. 18, 2024

(51) Int. Cl. H01L 21/768

(52) U.S. Cl. CPC H01L 21/76894; H01L 21/76834

(57) ABSTRACT

Provided is a method of fabricating a package structure including: forming a first bonding layer over a first surface of a first die; forming a release structure over a first carrier; bonding the first die to the first carrier by contacting the first bonding layer with the release structure; performing a laser process to divide the release structure into a first portion and a second portion, thereby debonding the first carrier from the first die; and performing a first removal process on the first portion of the release structure over the first carrier to expose a surface of the first carrier. The cleaned first carrier can be reused to fabricate another package structure, thereby reducing manufacturing costs and be greener or more environmentally friendly.

### BACKGROUND

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

Although existing methods of fabricating package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8A-8B, and 9A-9B are cross-sectional views of intermediate stages in the fabricating of a package structure, in accordance with some embodiments.

FIGS. 10, 11, 12A-12B, and 13A-13B are cross-sectional views of intermediate stages in the fabricating of a package structure, in accordance with some alternative embodiments.

FIGS. 14, 15, 16A-16B, and 17A-17B are cross-sectional views of intermediate stages in the fabricating of a package structure, in accordance with some other embodiments.

FIGS. 18, 19, 20A-20B, and 21A-21B are cross-sectional views of intermediate stages in the fabricating of a package structure, in accordance with some alternative embodiments.

FIGS. 22, 23, 24A-24B, and 25A-25B are cross-sectional views of intermediate stages in the fabricating of a package structure, in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

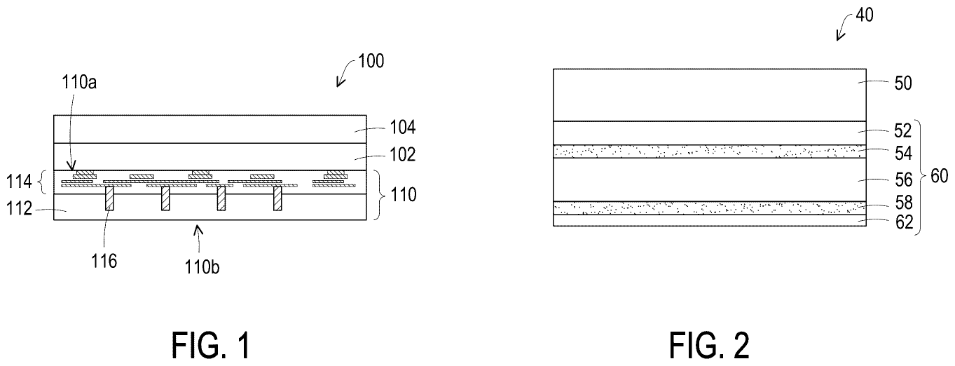

FIGS. 1, 2, 3, 4, 5, 6, 7, 8A-8B, and 9A-9B are cross-sectional views of intermediate stages in the fabricating of a package structure, in accordance with some embodiments.

Referring to FIG. 1, a first die 110 is provided. In some embodiments, the first die 110 may include a semiconductor substrate 112, an interconnect structure 114, and a plurality of through substrate vias (TSVs) 116. The first die 110 as illustrated in FIG. 1 can be obtained or formed. The first die 110 has a frontside 110a and a backside 110b opposite to the frontside 110a. In some embodiments, the first die 110 may be an interposer and does not include active devices therein, although the interposer may include passive devices. In some embodiments, the first die 110 includes active devices (e.g., transistors or memory devices) formed in and/or on the front surface of the semiconductor substrate 112. The semiconductor substrate 112 may be a bulk semiconductor substrate, a semiconductor-on-insulator (SOI) substrate, a multi-layered semiconductor substrate, or the like. The semiconductor substrate 112 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used.

The interconnect structure 114 is disposed over the semiconductor substrate 112, and is used to electrically connect the devices (if any) of the semiconductor substrate 112 and/or the devices attached to the interconnect structure 114. The interconnect structure 114 may include one or more dielectric layer(s) and respective metallization layer(s) in the dielectric layer(s). Acceptable dielectric materials for the dielectric layers include an oxide, a nitride, a carbide, a combination thereof, or the like. For example, the dielectric material may include silicon oxide, aluminum oxide, silicon nitride, silicon oxynitride, silicon carbide, silicon oxycarbide, silicon carbonitride, silicon oxycarbonitride, a combination thereof, or the like. Other dielectric materials may also be used, such as a polymer such as polybenzoxazole (PBO), polyimide, a benzocyclobutene (BCB) based polymer, or the like. The metallization layer(s) may include conductive vias and/or conductive lines to interconnect any devices together and/or to an external device. The metallization layer(s) may be formed of a conductive material, such as a metal, which may be copper, cobalt, aluminum, gold, combinations thereof, or the like. The interconnect structure 114 may be formed by a damascene process, such as a single damascene process, a dual damascene process, a combination therefore, or the like.

The TSVs 116 may extend into the interconnect structure 114 and/or the semiconductor substrate 112. The TSVs 116 are electrically connected to metallization layer(s) of the interconnect structure 114. As an example to form the TSVs 116, recesses can be formed in the interconnect structure 114 and/or the semiconductor substrate 112 by, for example, etching, milling, laser techniques, a combination thereof, and/or the like. A thin dielectric material may be formed in the recesses, such as by using an oxidation technique. A thin barrier layer may be conformally deposited in the openings, such as by chemical vapor deposition (CVD), atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer are removed from a surface of the interconnect structure 114 or the semiconductor substrate 112 by, for example, a chemical-mechanical polish (CMP). Remaining portions of the barrier layer and conductive material form the TSVs 116. On the other hand, as shown in FIG. 1, the TSVs 116 may buried within the backside 110b of the first die 110.

Next, a first dielectric layer 102 and a second dielectric layer 104 are formed on the frontside 110a of the first die 110, thereby accomplishing a first tier 100. In some embodiments, the first dielectric layer 102 and the second dielectric layer 104 may be formed of a dielectric material, which may be deposited by any suitable method, such as CVD, plasma-enhanced CVD (PECVD), or FCVD. The applicable dielectric material of the first dielectric layer 102 and the second dielectric layer 104 may include silicon oxide, aluminum oxide, silicon nitride; silicon oxynitride, silicon carbide, silicon oxycarbide, silicon carbonitride, silicon oxycarbonitride, phospho-silicate glass (PSG), boro-silicate glass (BSG), boron-doped phospho-silicate glass (BPSG), undoped silicate glass (USG), a combination thereof, or the like. In the present embodiment, the first dielectric layer 102 and the second dielectric layer 104 have different dielectric materials. For example, the first dielectric layer 102 is a silicon oxide layer, while the second dielectric layer 104 is a USG layer. A planarization process may be performed to level the top surface of the second dielectric layer 104, so that the first tier 100 is prepared for bonding. Herein, the second dielectric layer 104 may be referred to as a first bonding layer 104.

Referring to FIG. 2, a first carrier 50 is provided. In some embodiments, the first carrier 50 may be a semiconductor carrier, a glass carrier, a ceramic carrier, or the like. The first carrier 50 may be a silicon wafer or a panel, so that multiple layers and/or films can be formed on the first carrier 50.

Next, a release structure 60 is formed over the first carrier 50, thereby accomplishing a carrier structure 40. Specifically, the release structure 60 may include an adhesive layer 52, a release layer 54, a heat insulation layer 56, a reflection layer 58, and a second bonding layer 62 sequentially stacked from the deposition surface of the first carrier 50 (e.g., the lower surface of the first carrier 50 in FIG. 2).

In some embodiments, the adhesive layer 52 may include a dielectric material, such as silicon oxide, aluminum oxide, silicon nitride, silicon oxynitride, silicon carbide, silicon oxycarbide, silicon carbonitride, silicon oxycarbonitride, a combination thereof, or the like. The adhesive layer 52 can increase the adhesion between the first carrier 50 and the release layer 54. In some embodiments, the release layer 54 includes a material that is used to absorb a laser and then decompose during subsequent laser process. In this case, the release layer 54 may be but not limited to a titanium nitride (TiN) layer. In some embodiments, the heat insulation layer 56 may include a dielectric material, such as silicon oxide, aluminum oxide, silicon nitride, silicon oxynitride, silicon carbide, silicon oxycarbide, silicon carbonitride, silicon oxycarbonitride, a combination thereof, or the like. The heat insulation layer 56 may have the thermal insulation effect to prevent the heat (approximately greater than 1000° C.) generated by the subsequent laser process from affecting the devices of the first die 110 after bonding (FIG. 1). In such embodiment, the heat insulation layer 56 may have a thickness greater than 4 kÅ for further thermal insulation. In some embodiments, the reflection layer 58 can reflect the laser from the subsequent laser process to prevent the laser from affecting the devices of the first die 110 after bonding (FIG. 1). The reflection layer 58 may include a metal material, a barrier metal material, such as titanium nitride (TiN). In some embodiments, the second bonding layer 62 may include a dielectric material, such as silicon oxide, aluminum oxide, silicon nitride, silicon oxynitride, silicon carbide, silicon oxycarbide, silicon carbonitride, silicon oxycarbonitride, a combination thereof, or the like. A planarization process may be performed to level the top surface of the second bonding layer 62, so that the carrier structure 40 is prepared for bonding.

Although this method and other methods illustrated and/or described herein are illustrated as a series of acts or events, it will be appreciated that the present disclosure is not limited to the illustrated ordering or acts. For example, the carrier structure 40 may be formed before or after forming the first tier 100.

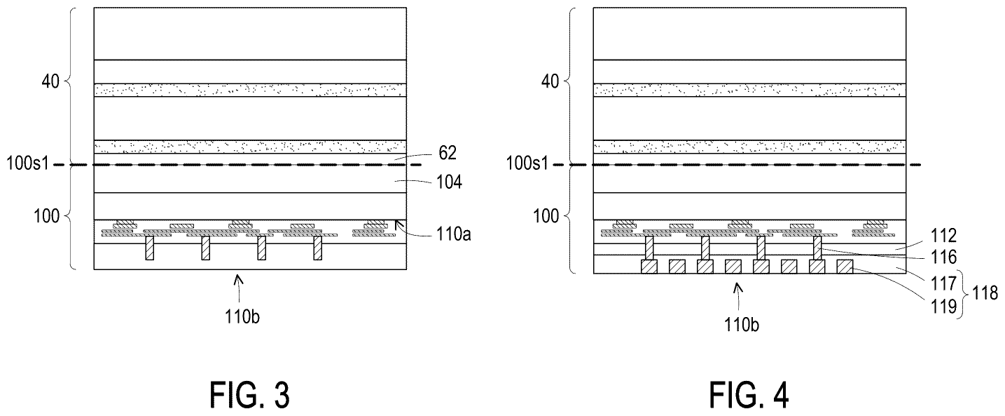

Referring to FIG. 3, the carrier structure 40 is bonded to the first tier 100. Specifically, the first carrier 50 may be bonded to the frontside 110a of the first die 110 by contacting the first bonding layer 104 with the second bonding layer 62 at a bonding interface 100s1. The bonding of the first bonding layer 104 to the second bonding layer 62 may be achieved through fusion bonding, for example, with Si—O—Si bonds being formed to join bond the first bonding layer 104 to the second bonding layer 62. Other bonds may be formed to join bond the first bonding layer 104 to the second bonding layer 62, such as Si—N—Si bonds.

Referring to FIG. 4, the first die 110 is thinned to expose the TSVs 116 at the backside 110b. Exposure of the TSVs 116 may be accomplished by a thinning process, such as a grinding process, a CMP, an etch-back, combinations thereof, or the like. In the illustrated embodiment, a recessing process is performed to recess the back surface of the semiconductor substrate 112 such that the TSVs 116 protrude from the semiconductor substrate 112 at the backside 110b. The recessing process may be, e.g., a suitable etch-back process, CMP, or the like. In some embodiments, the thinning process for exposing the TSVs 116 includes a CMP, and the TSVs 116 may protrude from the semiconductor substrate 112 as a result of dishing that occurs during the CMP or a separate recess etch process. A bonding dielectric layer 117 may be formed at the backside 110b to laterally surround the protruding portions of the TSVs 116. In detail, the bonding dielectric layer 117 may bury the protruding portions of the TSVs 116. In some embodiments, the bonding dielectric layer 117 is formed of a silicon-containing insulator, such as silicon nitride, silicon oxide, silicon oxynitride, or the like, and may be formed by a suitable deposition method such as spin coating, CVD, plasma-enhanced CVD (PECVD), high-density plasma CVD (HDP-CVD), or the like.

Then, a bonding metal layer 119 may be formed in the bonding dielectric layer 117 to accomplish a first bonding structure 118. Specifically, a portion of the bonding metal layer 119 is in direct contact with the protruding portions of the TSVs 116, while another portion of the bonding metal layer 119 is electrically floating. In some embodiments, the bonding metal layer 119 may be formed of a conductive material, such as a metal, which may be copper, cobalt, aluminum, gold, combinations thereof, or the like. The bonding metal layer 119 may be formed by a damascene process, such as a single damascene process, a dual damascene process, a combination therefore, or the like. A planarization process such CMP may be performed to level the top surfaces of the bonding metal layer 119 and bonding dielectric layer 117, so that the first bonding structure 118 is prepared for bonding.

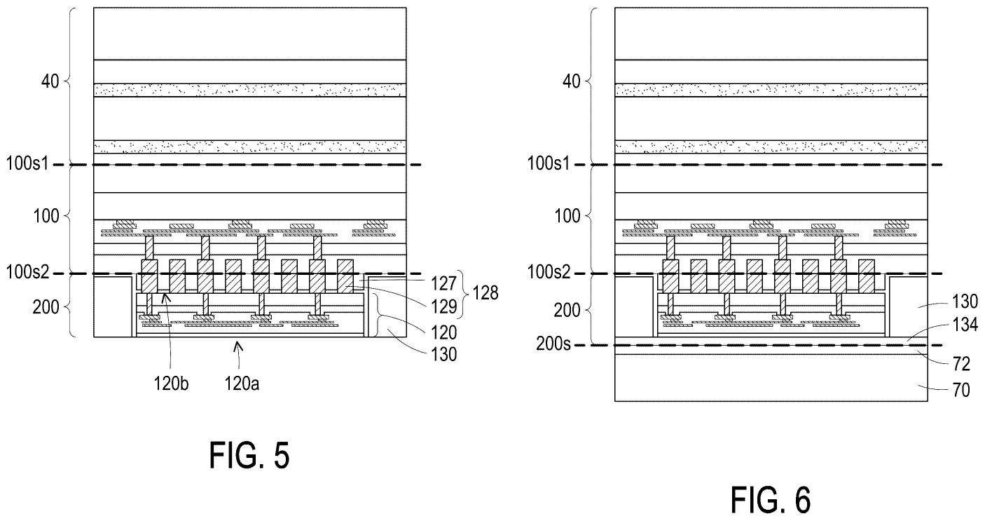

Referring to FIG. 5, a second die 120 is bonded to the first die 110. Specifically, the second die 120 may have a frontside 120a and a backside 120b opposite to each other. In addition, the second die 120 may have a semiconductor substrate, an interconnect structure on the semiconductor substrate, and a plurality of TSVs penetrating through the semiconductor substrate. A second bonding structure 128 may be formed over the backside 120b of the second die 120. In some embodiments, the second bonding structure 128 may include a bonding dielectric layer 127 and a bonding metal layer 129 formed in the bonding dielectric layer 127. A planarization process such CMP may be performed to level the top surfaces of the bonding metal layer 129 and bonding dielectric layer 127, so that the second bonding structure 128 is prepared for bonding. After forming the second bonding structure 128, the second die 120 may be bonded to the first die 110 by contacting the first bonding structure 118 with the second bonding structure 128 at a bonding interface 100s2. The bonding may include direct bonding, which includes the bonding of bonding metal layers 119 and 129 through metal-to-metal direct bonding, and the bonding of bonding dielectric layers 117 and 127 through fusion bonding. Accordingly, the devices of the first die 110 may be electrically connected to the devices of the second dies 120 through the bonding metal layers 119 and 129 and the TSVs 116. Although the bonding between the first die 110 and the second die 120 illustrated in FIG. 5 is a back-to-back bonding, the embodiments of the present disclosure are not limited thereto. In other embodiments, the first die 110 may be bonded to the second die 120 by a front-to-back bonding, a front-to-front bonding, or a back-to-front bonding.

In some embodiments, the second die 120 may be an integrated circuit die, a stack of integrated circuit dies, a memory die, or a stack of memory dies. The second die 120 may have a different function than a function of the first die 110, although they can have same or similar function. For example, the first die 110 may be a logic device, such as a central processing unit (CPU), graphics processing unit (GPU), system-on-a-chip (SoC), microcontroller, application-specific integrated circuit (ASIC), or the like. The second die 120 may be a memory device, such as a dynamic random-access memory (DRAM) device, static random access memory (SRAM) device, hybrid memory cube (HMC) module, a high bandwidth memory (HBM) module, or the like. As shown in FIG. 5, the size (e.g., width, length, or area) of the first die 110 may be greater than the size of the second die 120. In such embodiment, the first die 110 may be a logic wafer, the second die 120 may be a memory chip, and the second die 120 may be stacked on the first die 110 to form a system on integrated chip (SoIC) structure. Although only one second die 120 is bonded to the first die 110 illustrated in FIG. 5, the embodiments of the present disclosure are not limited thereto. In other embodiments, the number of the second die 120 bonded to the first die 110 can be adjusted by the needs.

After bonding the second die 120 to the first die 110, an insulating material 130 may be formed to laterally encapsulate sidewalls of the second die 120, thereby accomplishing a second tier 200. In some embodiments, the insulating material 130 may be formed of a dielectric material, such as an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as CVD, ALD, or the like. In addition, the insulating material 130 may include a single-layered structure, a bi-layered structure, or a multi-layered structure. Initially, the insulating material 130 may bury or cover the second die 120. A planarization process may be performed to level surfaces of the insulating material 130 and the second die 120, so that the second tier 200 is prepared for bonding. Herein, the insulating material 130 may be referred to as a gap-filling material.

Referring to FIG. 6, a second carrier 70 is bonded to the second tier 200. Specifically, the second carrier 70 may be bonded to the second tier 200 by contacting a bonding layer 72 with another bonding layer 134 at a bonding interface 200s. The bonding layer 72 may be formed on the second carrier 70. The bonding layer 134 may be formed to cover the frontside 120a of the second die 120 and the insulating material 130. In some embodiments, the bonding layers 72 and 134 may include a dielectric material, such as silicon oxide, aluminum oxide, silicon nitride, silicon oxynitride, silicon carbide, silicon oxycarbide, silicon carbonitride, silicon oxycarbonitride, a combination thereof, or the like. The bonding layers 72 and 134 may have the same dielectric material or different dielectric materials. The bonding of the bonding layer 72 to the bonding layer 134 may be achieved through fusion bonding, for example, with Si—O—Si bonds being formed to join bond the bonding layer 72 to the bonding layer 134. Other bonds may be formed to join bond the bonding layer 72 to the bonding layer 134, such as Si—N—Si bonds.

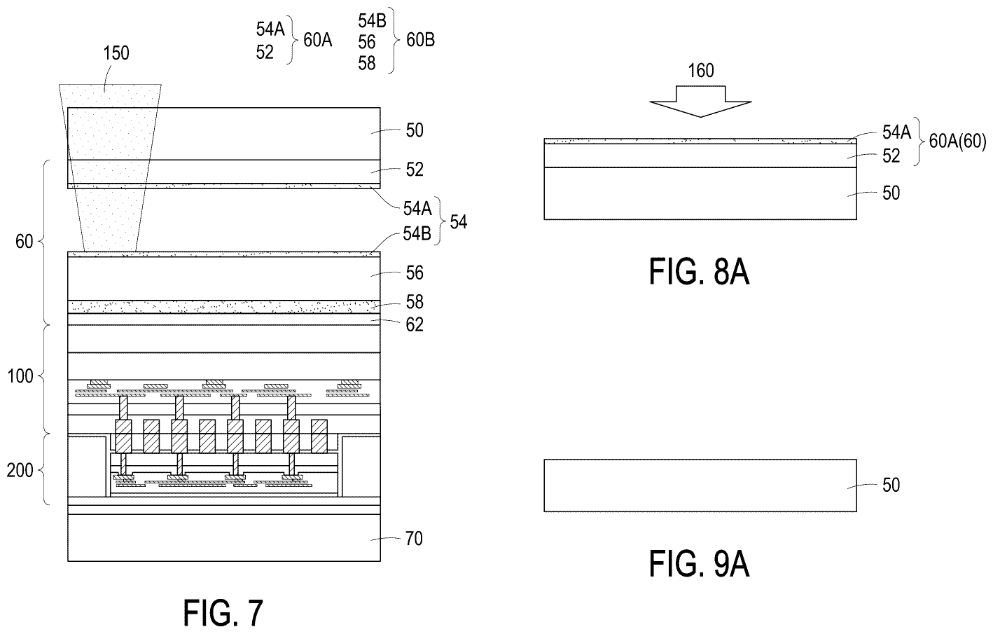

Referring to FIG. 7, a laser process 150 is performed to divide the release structure 60 into a first portion 60A and a second portion 60B, thereby debonding the first carrier 50 from the first tier 100 (or first die 110). In some embodiments, the laser process 150 may include to use an infrared (IR) laser with a wavelength of 1.9-2.0 μm, so that the IR laser penetrates the first carrier 50 and the adhesive layer 52 and is absorbed by the release layer 54. The release layer 54 may be vaporized and broken into a first sub-layer 54A and a second sub-layer 54B due to the absorption of the IR laser. In this case, the release layer 54 may be referred to as a laser decomposition layer. The first portion 60A may be disposed on the first carrier 50 and includes the adhesive layer 52 and the first sub-layer 54A. The second portion 60B may be disposed on the first tier 100 and includes the second bonding layer 62, the reflection layer 58, the heat insulation layer 56, and the second sub-layer 54B.

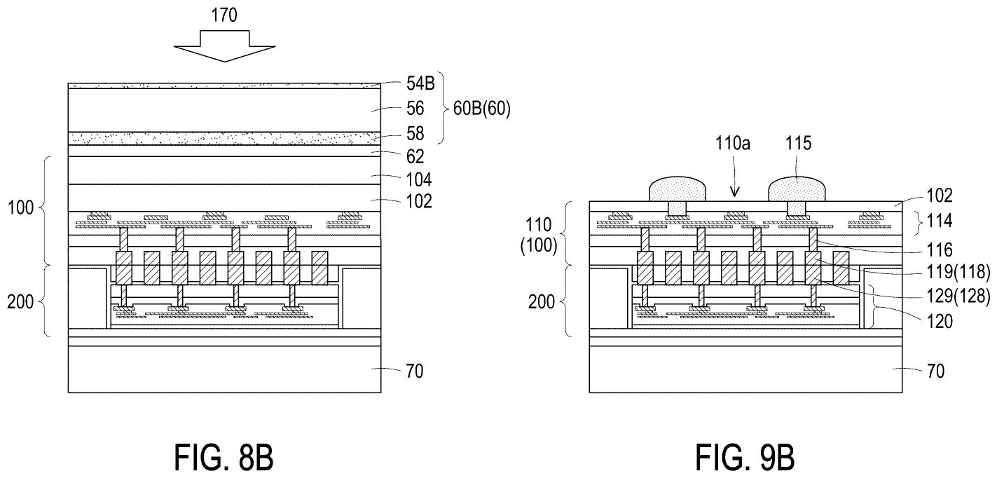

Referring to FIG. 8A and FIG. 9A, a first removal process 160 is performed on the first portion 60A of the release structure 60 over the first carrier 50. In some embodiments, the first removal process 160 may be a wet etching process having at least two etching steps. Specifically, a first etching step may be used to remove the first sub-layer 54A, and the second etching step may be used to remove the adhesive layer 52. Since the first sub-layer 54A and the adhesive layer 52 have different materials, the first and second etching steps include different etchants. After performing the first removal process 160, the first portion 60A of the release structure 60 is completely removed to expose the surface of the first carrier 50. It should be noted that, in some embodiments, the cleaned first carrier 50 can be reused to fabricate another package structure. Compared with the conventional removal carrier process by grinding and/or etching, the laser process for debonding the carrier of the present embodiment can recycle and/or reuse the first carrier 50, so as to effectively reduce manufacturing costs and be greener or more environmentally friendly.

On the other hand, as shown in FIG. 8B, a second removal process 170 is performed on the second portion 60B of the release structure 60 over the first tier 100. In some embodiments, the second removal process 170 may include a wet etching process and a grinding process. Specifically, the wet etching process may include at least three etching steps to remove the second sub-layer 54B, the heat insulation layer 56 and the reflection layer 58 respectively, and stop on the second bonding layer 62. The grinding process may remove the second bonding layer 62, the first bonding layer 104, and a portion of the first dielectric layer 102. However, the embodiments of the present disclosure are not limited thereto, more or fewer removal steps may also be included in the second removal process.

Referring to FIG. 9B, a plurality of connectors 115 are formed over the frontside 110a of the first die 110 for external connections. In some embodiments, the connectors 115 may be formed of a reflowable conductive material, such as solder, and may further include other conductive materials such as copper, aluminum, gold, nickel, silver, palladium, tin, lead, the like, or a combination thereof. The connectors 115 may penetrate through the first dielectric layer 102 to electrically connect the interconnect structure 114. As such, the external connections may be electrically connected to the second die 120 through the connectors 115, the interconnect structure 114, the TSVs 116, and the bonding metal layers 119 and 129. Although this method and other methods illustrated and/or described herein are illustrated as a series of acts or events, it will be appreciated that the present disclosure is not limited to the illustrated ordering or acts. For example, the steps illustrated in FIG. 8A to FIG. 9A may be formed before or after forming the steps illustrated in FIG. 8B to FIG. 9B.

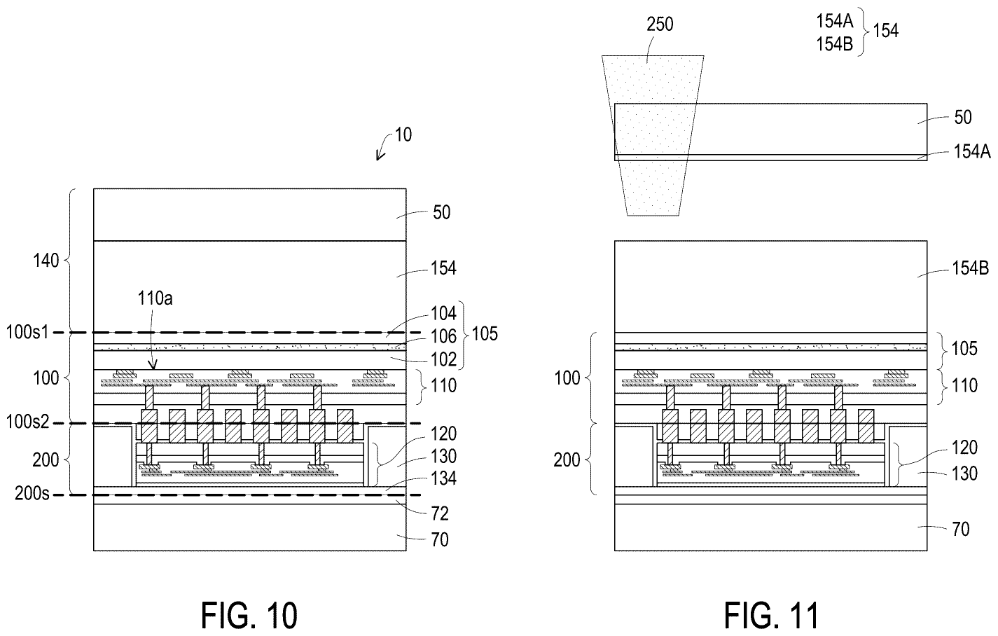

FIGS. 10, 11, 12A-12B, and 13A-13B are cross-sectional views of intermediate stages in the fabricating of a package structure, in accordance with some alternative embodiments.

Referring to FIG. 10, an initial structure 10 may be formed by similar processes as illustrated in FIG. 1 to FIG. 6, but the carrier structure 40 is replaced by another carrier structure 140. Specifically, a first carrier 50 is provided. Then, a release layer 154 is formed over the first carrier 50, thereby accomplishing the carrier structure 140. The release layer 154 may be in direct contact with the first carrier 50. In some embodiments, the release layer 154 includes a material that is used to absorb a laser and then decompose during subsequent laser process. In this case, the release layer 154 may be but not limited to an oxide layer, such as silicon oxide layer.

In addition, a reflection layer 106 may be formed between the first dielectric layer 102 and the first bonding layer 104 to form a bonding structure 105 over the frontside 110a of the first die 110. In some embodiments, the reflection layer 106 can reflect the laser from the subsequent laser process to prevent the laser from affecting the devices of the first die 110. The reflection layer 106 may include a metal material, a barrier metal material, such as titanium nitride (TiN). From another perspective, the initial structure 10 may include the first carrier 50 bonded to a package, wherein the package may include the first tier 100 stacked on a first surface of the second tier 200, and the second carrier 70 bonded to a second surface of the second tier 200 opposite to the first surface.

Referring to FIG. 11, a laser process 250 is performed to divide the release layer 154 into a first portion 154A and a second portion 154B, thereby debonding the first carrier 50 from the first tier 100 (or first die 110). In some embodiments, the laser process 250 may include to use an infrared (IR) laser with a wavelength of 9.0-10.0 μm, so that the IR laser penetrates the first carrier 50 and is absorbed by the release layer 154. After absorbing the IR laser, the increased thermal stress between the first carrier 50 and the release layer 154 will result in the crack of the release layer 154 due to a mismatch of coefficient of thermal expansion (CTE) between the first carrier 50 (e.g., Si) and the release layer 154 (e.g., silicon oxide). In this case, the release layer 154 may be referred to as a laser decomposition layer. The first portion 154A may be disposed on the first carrier 50, and the second portion 154B may be disposed on the first tier 100.

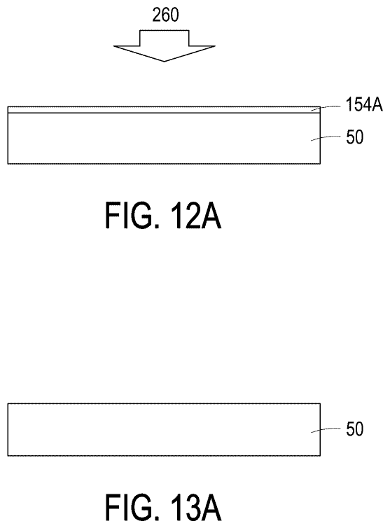

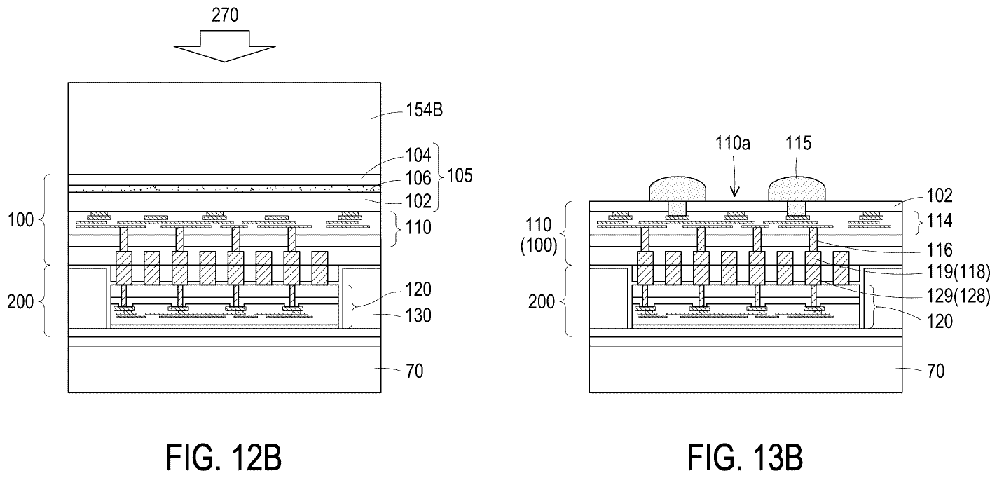

Referring to FIG. 12A and FIG. 13A, a first removal process 260 is performed on the first portion 154A of the release layer 154 over the first carrier 50. In some embodiments, the first removal process 260 may be a wet etching process which is used to remove the first portion 154A. After performing the first removal process 260, the first portion 154A of the release layer 154 is completely removed to expose the surface of the first carrier 50. It should be noted that, in some embodiments, the cleaned first carrier 50 can be reused to fabricate another package structure. Compared with the related removal carrier process by grinding and/or etching, the laser process for debonding the carrier of the present embodiment can recycle and/or reuse the first carrier 50, so as to effectively reduce manufacturing costs and be greener or more environmentally friendly.

On the other hand, as shown in FIG. 12B, a second removal process 270 is performed on the second portion 154B of the release layer 154 over the first tier 100. In some embodiments, the second removal process 270 may include a wet etching process and a grinding process. Specifically, the wet etching process may include at least two etching steps to remove the second portion 154B and the first bonding layer 104 respectively, and stop on the reflection layer 106. The grinding process may remove the reflection layer 106 and a portion of the first dielectric layer 102. However, the embodiments of the present disclosure are not limited thereto, more or fewer removal steps may also be included in the second removal process.

Referring to FIG. 13B, a plurality of connectors 115 are formed over the frontside 110a of the first die 110 for external connections. In some embodiments, the connectors 115 may be formed of a reflowable conductive material, such as solder, and may further include other conductive materials such as copper, aluminum, gold, nickel, silver, palladium, tin, lead, the like, or a combination thereof. The connectors 115 may penetrate through the first dielectric layer 102 to electrically connect the interconnect structure 114. As such, the external connections may be electrically connected to the second die 120 through the connectors 115, the interconnect structure 114, the TSVs 116, and the bonding metal layers 119 and 129. Although this method and other methods illustrated and/or described herein are illustrated as a series of acts or events, it will be appreciated that the present disclosure is not limited to the illustrated ordering or acts. For example, the steps illustrated in FIG. 12A to FIG. 13A may be formed before or after forming the steps illustrated in FIG. 12B to FIG. 13B.

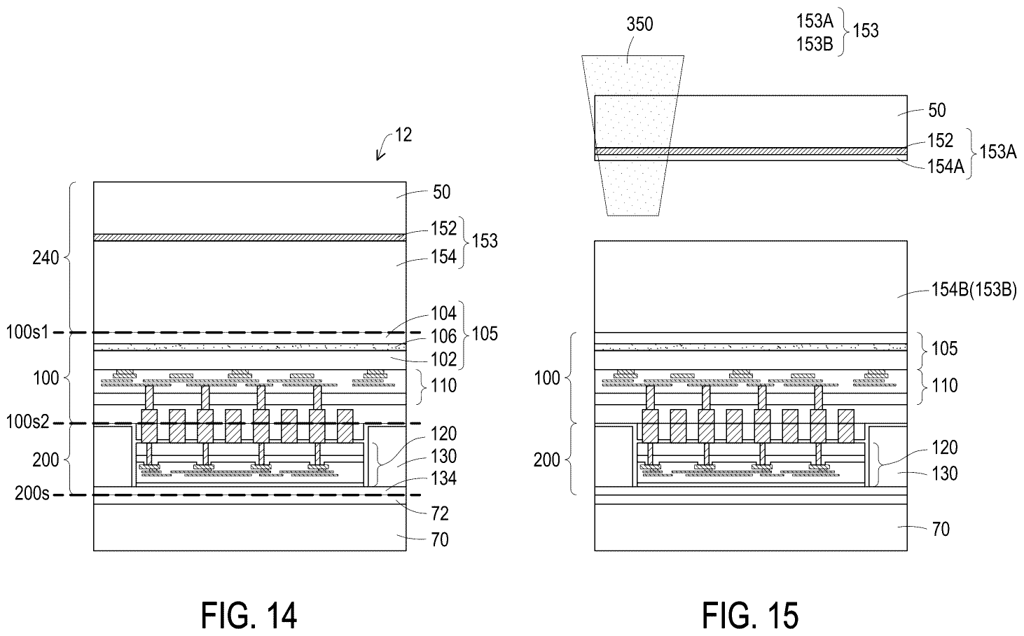

FIGS. 14, 15, 16A-16B, and 17A-17B are cross-sectional views of intermediate stages in the fabricating of a package structure, in accordance with some other embodiments.

Referring to FIG. 14, an initial structure 12 may be formed by similar processes as illustrated in FIG. 1 to FIG. 6, but the carrier structure 40 is replaced by another carrier structure 240. Specifically, a first carrier 50 is provided. Then, a release structure 153 is formed over the first carrier 50, thereby accomplishing the carrier structure 240. The release structure 153 may include a blocking layer 152 sandwiched between and in direct contact with the first carrier 50 and a release layer 154. In some embodiments, the blocking layer 152 may be but not limited to a silicon nitride (SiN) layer. The blocking layer 152 can prevent the surface of the first carrier 50 from being damage during the subsequent debonding process or removal process, thereby increasing the reuse lifetime of the first carrier 50. In some embodiments, the release layer 154 includes a material that is used to absorb a laser and then decompose during subsequent laser process. In this case, the release layer 154 may be but not limited to an oxide layer, such as silicon oxide layer.

In addition, a reflection layer 106 may be formed between the first dielectric layer 102 and the first bonding layer 104 to form a bonding structure 105 over the frontside 110a of the first die 110. In some embodiments, the reflection layer 106 can reflect the laser from the subsequent laser process to prevent the laser from affecting the devices of the first die 110. The reflection layer 106 may include a metal material, a barrier metal material, such as titanium nitride (TiN).

Referring to FIG. 15, a laser process 350 is performed to divide the release structure 153 into a first portion 153A and a second portion 153B, thereby debonding the first carrier 50 from the first tier 100 (or first die 110). In some embodiments, the laser process 350 may include to use an infrared (IR) laser with a wavelength of 9.0-10.0 μm, so that the IR laser penetrates the first carrier 50 and the blocking layer 152 and is absorbed by the release layer 154. After absorbing the IR laser, the increased thermal stress between the first carrier 50 and the release layer 154 will result in the crack of the release layer 154 due to a mismatch of CTE between the first carrier 50 (e.g., Si) and the release layer 154 (e.g., silicon oxide). In this case, the first portion 153A is disposed on the first carrier 50 and includes the blocking layer 152 and a first sub-layer 154A of the release layer 154. The second portion 153B is disposed on the first tier 100 and includes a second sub-layer 154B of the release layer 154.

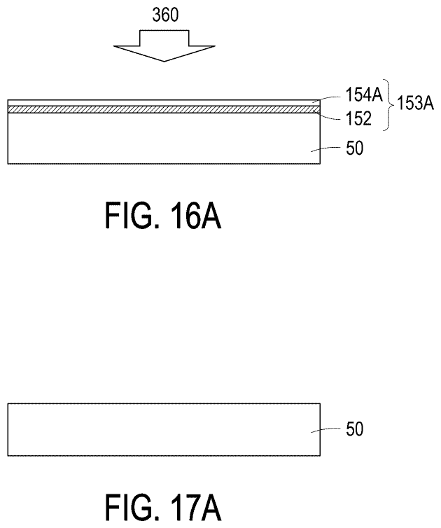

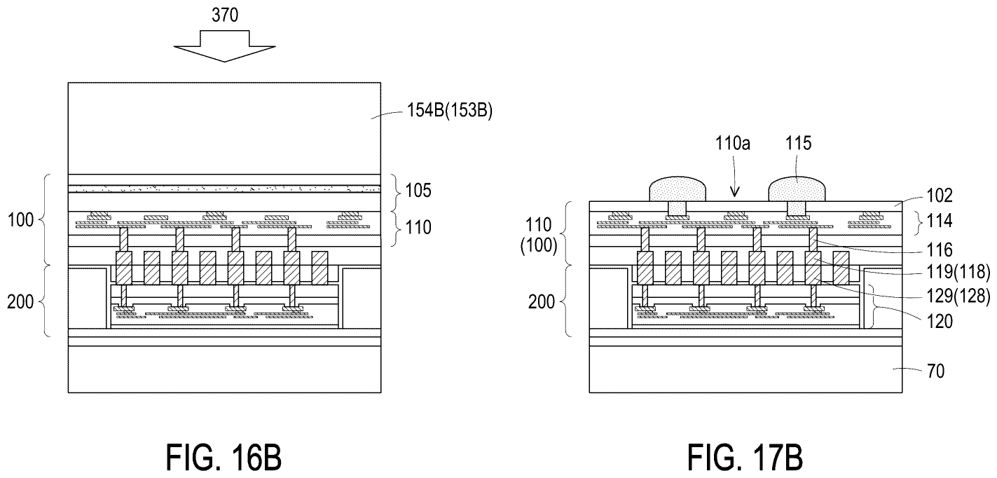

Referring to FIG. 16A and FIG. 17A, a first removal process 360 is performed on the first portion 153A of the release structure 153 over the first carrier 50. In some embodiments, the first removal process 360 may be a wet etching process having at least two etching steps. Specifically, a first etching step may be used to remove the first sub-layer 154A, and the second etching step may be used to remove the blocking layer 152. Since the first sub-layer 154A and the blocking layer 152 have different materials, the first and second etching steps include different etchants. After performing the first removal process 360, the first portion 153A of the release structure 153 is completely removed to expose the surface of the first carrier 50. It should be noted that, in some embodiments, the cleaned first carrier 50 can be reused to fabricate another package structure. Compared with the related removal carrier process by grinding and/or etching, the laser process for debonding the carrier of the present embodiment can recycle and/or reuse the first carrier 50, so as to effectively reduce manufacturing costs and be greener or more environmentally friendly.

On the other hand, as shown in FIG. 16B, a second removal process 370 is performed on the second portion 153B of the release structure 153 over the first tier 100. In some embodiments, the second removal process 370 may include a wet etching process and a grinding process. Specifically, the wet etching process may include at least two etching steps to remove the second sub-layer 154B and the first bonding layer 104 respectively, and stop on the reflection layer 106. The grinding process may remove the reflection layer 106 and a portion of the first dielectric layer 102. However, the embodiments of the present disclosure are not limited thereto, more or fewer removal steps may also be included in the second removal process.

Referring to FIG. 17B, a plurality of connectors 115 are formed over the frontside 110a of the first die 110 for external connections. In some embodiments, the connectors 115 may be formed of a reflowable conductive material, such as solder, and may further include other conductive materials such as copper, aluminum, gold, nickel, silver, palladium, tin, lead, the like, or a combination thereof. The connectors 115 may penetrate through the first dielectric layer 102 to electrically connect the interconnect structure 114. As such, the external connections may be electrically connected to the second die 120 through the connectors 115, the interconnect structure 114, the TSVs 116, and the bonding metal layers 119 and 129. Although this method and other methods illustrated and/or described herein are illustrated as a series of acts or events, it will be appreciated that the present disclosure is not limited to the illustrated ordering or acts. For example, the steps illustrated in FIG. 16A to FIG. 17A may be formed before or after forming the steps illustrated in FIG. 16B to FIG. 17B.

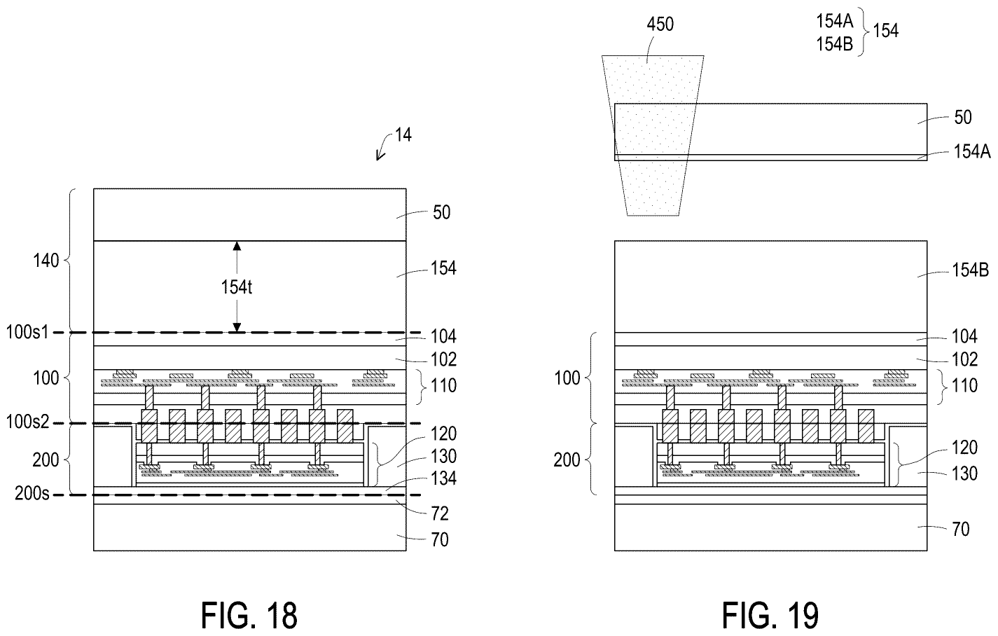

FIGS. 18, 19, 20A-20B, and 21A-21B are cross-sectional views of intermediate stages in the fabricating of a package structure, in accordance with some alternative embodiments.

Referring to FIG. 18, an initial structure 14 may be formed by similar processes as illustrated in FIG. 1 to FIG. 6, but the carrier structure 40 is replaced by another carrier structure 140. Specifically, a first carrier 50 is provided. Then, a release layer 154 is formed over the first carrier 50, thereby accomplishing the carrier structure 140. The release layer 154 may be in direct contact with the first carrier 50. In some embodiments, the release layer 154 includes a material that is used to absorb a laser and then decompose during subsequent laser process. In this case, the release layer 154 may be but not limited to an oxide layer, such as silicon oxide layer. It should be noted that the release layer 154 is thick enough to prevent the laser from affecting the devices of the first die 110. In such embodiment, the release layer 154 has a thickness 154 t greater than or equal to 5 kÅ, such as 5 kÅ to 10 kÅ, or the like. Since the release layer 154 has sufficient thickness to resist the laser, the reflection layer is not required to be formed under the release layer 154.

Referring to FIG. 19, a laser process 450 is performed to divide the release layer 154 into a first portion 154A and a second portion 154B, thereby debonding the first carrier 50 from the first tier 100 (or first die 110). In some embodiments, the laser process 450 may include to use an infrared (IR) laser with a wavelength of 9.0-10.0 μm, so that the IR laser penetrates the first carrier 50 and is absorbed by the release layer 154. After absorbing the IR laser, the increased thermal stress between the first carrier 50 and the release layer 154 will result in the crack of the release layer 154 due to a mismatch of CTE between the first carrier 50 (e.g., Si) and the release layer 154 (e.g., silicon oxide). In this case, the first portion 154A is disposed on the first carrier 50, and the second portion 154B is disposed on the first tier 100.

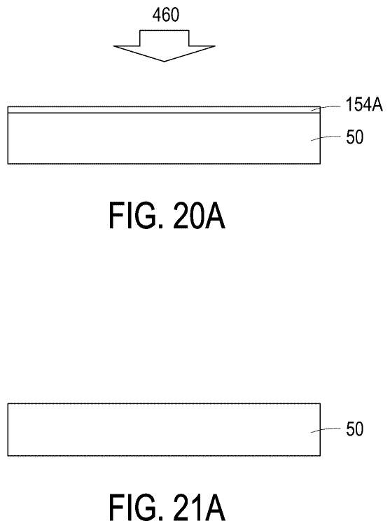

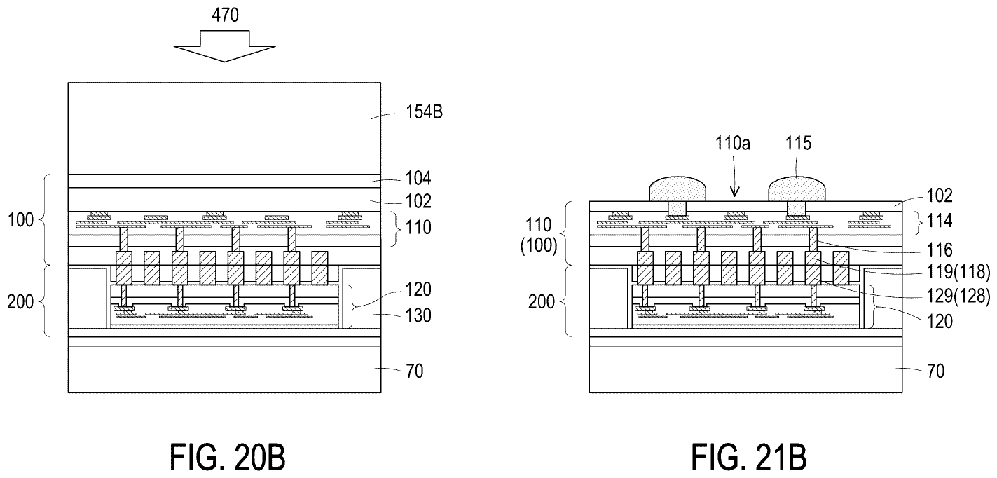

Referring to FIG. 20A and FIG. 21A, a first removal process 460 is performed on the first portion 154A of the release layer 154 over the first carrier 50. In some embodiments, the first removal process 460 may be a wet etching process which is used to remove the first portion 154A. After performing the first removal process 460, the first portion 154A of the release layer 154 is completely removed to expose the surface of the first carrier 50. It should be noted that, in some embodiments, the cleaned first carrier 50 can be reused to fabricate another package structure. Compared with the conventional removal carrier process by grinding and/or etching, the laser process for debonding the carrier of the present embodiment can recycle and/or reuse the first carrier 50, so as to effectively reduce manufacturing costs and be greener or more environmentally friendly.

On the other hand, as shown in FIG. 20B, a second removal process 470 is performed on the second portion 154B of the release layer 154 over the first tier 100. In some embodiments, the second removal process 470 may include a wet etching process and a grinding process. Specifically, the wet etching process may remove the second portion 154B, and stop on the first bonding layer 104. The grinding process may remove the first bonding layer 104 and a portion of the first dielectric layer 102. However, the embodiments of the present disclosure are not limited thereto, more or fewer removal steps may also be included in the second removal process.

Referring to FIG. 21B, a plurality of connectors 115 are formed over the frontside 110a of the first die 110 for external connections. In some embodiments, the connectors 115 may be formed of a reflowable conductive material, such as solder, and may further include other conductive materials such as copper, aluminum, gold, nickel, silver, palladium, tin, lead, the like, or a combination thereof. The connectors 115 may penetrate through the first dielectric layer 102 to electrically connect the interconnect structure 114. As such, the external connections may be electrically connected to the second die 120 through the connectors 115, the interconnect structure 114, the TSVs 116, and the bonding metal layers 119 and 129. Although this method and other methods illustrated and/or described herein are illustrated as a series of acts or events, it will be appreciated that the present disclosure is not limited to the illustrated ordering or acts. For example, the steps illustrated in FIG. 20A to FIG. 21A may be formed before or after forming the steps illustrated in FIG. 20B to FIG. 21B.

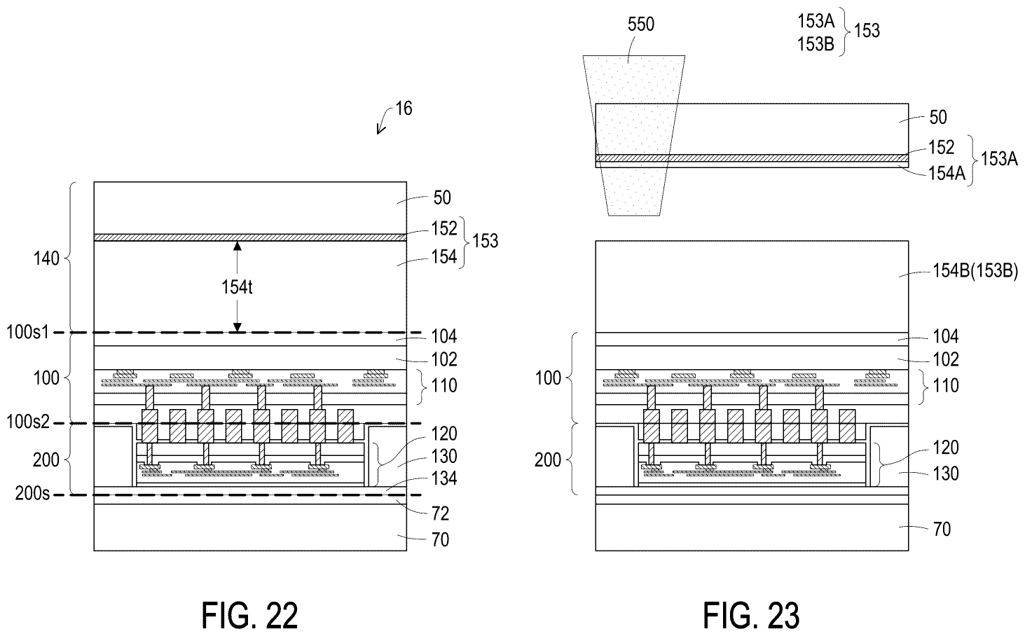

FIGS. 22, 23, 24A-24B, and 25A-25B are cross-sectional views of intermediate stages in the fabricating of a package structure, in accordance with some other embodiments.

Referring to FIG. 22, an initial structure 16 is similar to the initial structure 14, but the initial structure 16 further includes a blocking layer 152 sandwiched between the first carrier 50 and a release layer 154. In some embodiments, the blocking layer 152 may be but not limited to a silicon nitride (SiN) layer. The blocking layer 152 can prevent the surface of the first carrier 50 from being damage during the subsequent debonding process, thereby increasing the reuse lifetime of the first carrier 50. In addition, the release layer 154 of the initial structure 16 is thick enough to prevent the laser from affecting the devices of the first die 110. In such embodiment, the release layer 154 has a thickness 154 t greater than or equal to 5 kÅ, such as 5 kÅ to 10 kÅ, or the like. Since the release layer 154 has sufficient thickness to resist the laser, the reflection layer is not required to be formed under the release layer 154.

Referring to FIG. 23, a laser process 550 is performed to divide the release structure 153 into a first portion 153A and a second portion 153B, thereby debonding the first carrier 50 from the first tier 100 (or first die 110). In some embodiments, the laser process 550 may include to use an infrared (IR) laser with a wavelength of 9.0-10.0 μm, so that the IR laser penetrates the first carrier 50 and the blocking layer 152 and is absorbed by the release layer 154. After absorbing the IR laser, the increased thermal stress between the first carrier 50 and the release layer 154 will result in the crack of the release layer 154 due to a mismatch of CTE between the first carrier 50 (e.g., Si) and the release layer 154 (e.g., silicon oxide). In this case, the first portion 153A is disposed on the first carrier 50 and includes the blocking layer 152 and a first sub-layer 154A of the release layer 154. The second portion 153B is disposed on the first tier 100 and includes a second sub-layer 154B of the release layer 154.

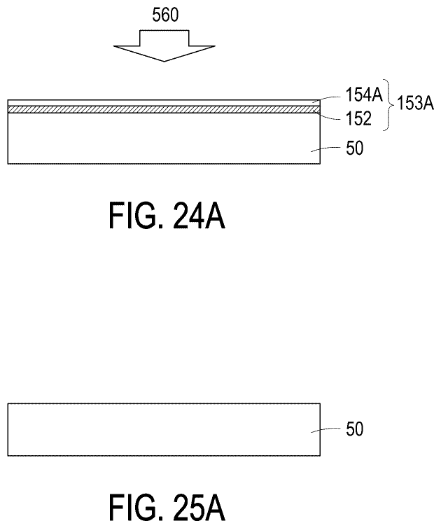

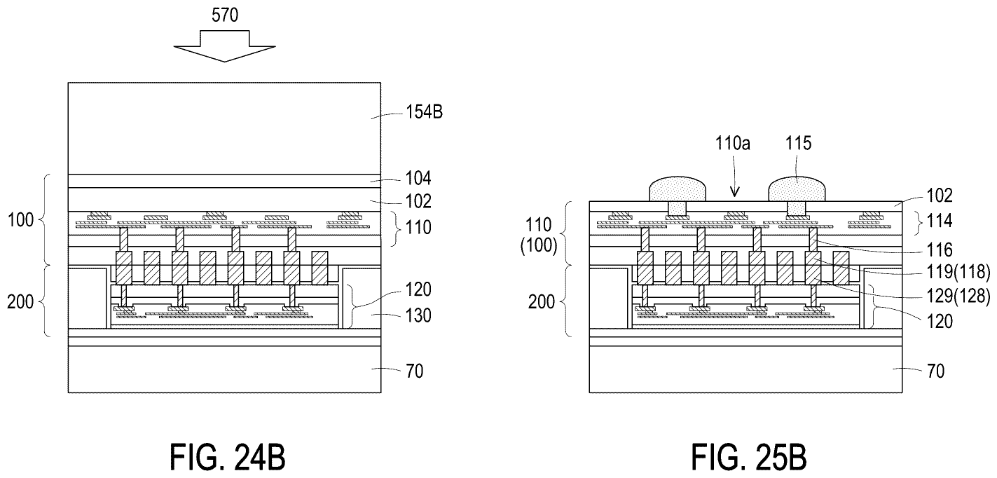

Referring to FIG. 24A and FIG. 25A, a first removal process 560 is performed on the first portion 153A of the release structure 153 over the first carrier 50. In some embodiments, the first removal process 560 may be a wet etching process having at least two etching steps. Specifically, a first etching step may be used to remove the first sub-layer 154A, and the second etching step may be used to remove the blocking layer 152. Since the first sub-layer 154A and the blocking layer 152 have different materials, the first and second etching steps include different etchants. After performing the first removal process 560, the first portion 153A of the release structure 153 is completely removed to expose the surface of the first carrier 50. It should be noted that, in some embodiments, the cleaned first carrier 50 can be reused to fabricate another package structure. Compared with the conventional removal carrier process by grinding and/or etching, the laser process for debonding the carrier of the present embodiment can recycle and/or reuse the first carrier 50, so as to effectively reduce manufacturing costs and be greener or more environmentally friendly.

On the other hand, as shown in FIG. 24B, a second removal process 570 is performed on the second portion 154B of the release layer 154 over the first tier 100. In some embodiments, the second removal process 570 may include a wet etching process and a grinding process. Specifically, the wet etching process may remove the second portion 154B and stop on the first bonding layer 104. The grinding process may remove the first bonding layer 104 and a portion of the first dielectric layer 102. However, the embodiments of the present disclosure are not limited thereto, more or fewer removal steps may also be included in the second removal process.

Referring to FIG. 25B, a plurality of connectors 115 are formed over the frontside 110a of the first die 110 for external connections. In some embodiments, the connectors 115 may be formed of a reflowable conductive material, such as solder, and may further include other conductive materials such as copper, aluminum, gold, nickel, silver, palladium, tin, lead, the like, or a combination thereof. The connectors 115 may penetrate through the first dielectric layer 102 to electrically connect the interconnect structure 114. As such, the external connections may be electrically connected to the second die 120 through the connectors 115, the interconnect structure 114, the TSVs 116, and the bonding metal layers 119 and 129. Although this method and other methods illustrated and/or described herein are illustrated as a series of acts or events, it will be appreciated that the present disclosure is not limited to the illustrated ordering or acts. For example, the steps illustrated in FIG. 24A to FIG. 25A may be formed before or after forming the steps illustrated in FIG. 24B to FIG. 25B.

According to some embodiments, a method of fabricating a package structure includes: forming a first bonding layer over a first surface of a first die; forming a release structure over a first carrier; bonding the first die to the first carrier by contacting the first bonding layer with the release structure; performing a laser process to divide the release structure into a first portion and a second portion, thereby debonding the first carrier from the first die; and performing a first removal process on the first portion of the release structure over the first carrier to expose a surface of the first carrier.

According to some embodiments, a method of fabricating a package structure includes: forming a release layer over a first carrier; bonding the first carrier to a frontside of a first die, so that the release layer is sandwiched between the first carrier and the frontside of the first die; performing a laser process to divide the release layer into a first portion and a second portion, thereby debonding the first carrier from the first die; and performing a second removal process on the second portion of the release layer over the frontside of the first die.

According to some embodiments, a method of fabricating a package structure includes: bonding a first carrier to a package wherein a laser decomposition layer is vertically disposed between the first carrier and the package; decomposing the laser decomposition layer to debond the first carrier from the package; performing a first removal process on the first carrier; and reusing the first carrier to fabricate another package structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a package structure, comprising:
forming a first bonding layer over a first surface of a first die;
forming a release structure over a first carrier;
bonding the first die to the first carrier by contacting the first bonding layer with the release structure;
performing a laser process to divide the release structure into a first portion and a second portion, thereby debonding the first carrier from the first die; and
performing a first removal process on the first portion of the release structure over the first carrier to expose a surface of the first carrier.

2. The method of claim 1, further comprising: reusing the first carrier to fabricate another package structure.

3. The method of claim 1, wherein after performing the first removal process, the first portion of the release structure over the first carrier is completely removed.

4. The method of claim 1, wherein the release structure comprises:
an adhesive layer disposed on and contacting the first carrier;
a release layer disposed on and contacting the adhesive layer;
a heat insulation layer disposed on and contacting the release layer;
a reflection layer disposed on and contacting the heat insulation layer; and
a second bonding layer disposed on and contacting the reflection layer, wherein the second bonding layer is sandwiched between the reflection layer and the first bonding layer.

5. The method of claim 4, wherein the release layer includes a titanium nitride (TiN) layer.

6. The method of claim 5, wherein the laser process comprises using an infrared (IR) laser with a wavelength of 1.9-2.0 μm, so that the IR laser penetrates the first carrier and the adhesive layer and is absorbed by the release layer.

7. The method of claim 1, wherein after performing the laser process, the method further comprises:
performing a second removal process on the second portion of the release structure over the first surface of the first die; and
forming a plurality of connectors over the first surface of the first die.

8. The method of claim 1, wherein before performing the laser process, the method further comprises:
forming a first bonding structure over a second surface of the first die opposite to the first surface;
forming a second bonding structure over a second die;
bonding the second die to the second die by contacting the second bonding structure with the first bonding structure;
forming an insulating material to encapsulate sidewalls of the second die; and
bonding a second carrier to the second die and the insulating material.

9. A method of fabricating a package structure, comprising:
forming a release layer over a first carrier;
bonding the first carrier to a frontside of a first die, so that the release layer is sandwiched between the first carrier and the frontside of the first die;
performing a laser process to divide the release layer into a first portion and a second portion, thereby debonding the first carrier from the first die; and
performing a second removal process on the second portion of the release layer over the frontside of the first die.

10. The method of claim 9, wherein the release layer is an oxide layer, and the release layer is in direct contact with the first carrier.

11. The method of claim 9, wherein the laser process comprises using an infrared (IR) laser with a wavelength of 9.0-10.0 μm, so that the IR laser penetrates the first carrier and is absorbed by the release layer.

12. The method of claim 9, further comprising: forming a blocking layer between the first carrier and the release layer.

13. The method of claim 12, wherein the blocking layer is a silicon nitride (SiN) layer.

14. The method of claim 9, further comprising: forming a first bonding structure over the frontside of the first die, wherein the first bonding structure comprises:
a dielectric layer disposed on the frontside of the first die;
a reflection layer disposed on the dielectric layer; and
a first bonding layer disposed on the reflection layer, wherein the first bonding layer is sandwiched between the reflection layer and the release layer.

15. The method of claim 9, further comprising:
performing a first removal process on the first portion of the release layer over the first carrier; and
after performing the first removal process, reusing the first carrier to fabricate another package structure.

16. The method of claim 9, wherein before performing the laser process, the method further comprises:
forming a second bonding structure over a backside of the first die;
forming a third bonding structure over a second die;
bonding the second die to the second die by contacting the third bonding structure with the second bonding structure;
forming an insulating material to encapsulate sidewalls of the second die; and
bonding a second carrier to the second die and the insulating material.

17. A method of fabricating a package structure, comprising:
bonding a first carrier to a package wherein a laser decomposition layer is vertically disposed between the first carrier and the package;
decomposing the laser decomposition layer to debond the first carrier from the package;
performing a first removal process on the first carrier; and
reusing the first carrier to fabricate another package structure.

18. The method of claim 17, wherein after performing the laser process, the method further comprises:
performing a second removal process and a grinding process on the package; and
forming a plurality of connectors over the package.

19. The method of claim 17, wherein the package comprises:
a first die;
a second die having a first surface and a second surface opposite to each other, the first die being bonded to the first surface of the second die;
a second carrier bonded to the second surface of the second die; and
an insulating material disposed between the first die and the second carrier, and laterally encapsulating sidewalls of the second die.

20. The method of claim 17, wherein decomposing the laser decomposition layer comprises: performing a laser process, wherein the laser process comprises using an infrared (IR) laser, so that the IR laser penetrates the first carrier and is absorbed by the laser decomposition layer.
